(19) United States
(12) Patent Application Publication
(10) Pub. No.: US 2023/0378010 A1
(43) Pub. Date: Nov. 23, 2023

(54) POWER SEMICONDUCTOR DEVICES HAVING MOISTURE BARRIERS

(71) Applicant: Wolfspeed, Inc., Durham, NC (US)

(72) Inventors: Dev Balaraman, Apex, NC (US); Geza Dezsi, Durham, NC (US); Daniel Richter, Raleigh, NC (US)

(21) Appl. No.: 17/747,128

(22) Filed: May 18, 2022

(51) Int. Cl. H01L 23/31; H01L 25/07; H01L 23/00; H01L 23/498; H01L 23/29

(52) U.S. Cl. CPC H01L 23/3135; H01L 25/072; H01L 24/48; H01L 23/49861; H01L 23/49811; H01L 23/49822; H01L 23/49833; H01L 23/49844; H01L 23/293; H01L 2224/48245; H01L 21/565

(57) ABSTRACT

A power semiconductor device comprises a package, a power semiconductor die within the package, and a moisture barrier on an upper surface and side surfaces of an exterior of the package.

### FIELD OF THE INVENTION

The present invention relates to power semiconductor devices and, more particularly, to packaged power semiconductor devices.

### BACKGROUND

Power semiconductor devices refer to devices that include one or more power semiconductor die that are designed to carry large currents and/or that are capable of blocking high voltages. Herein, a power semiconductor die refers to a semiconductor die that during normal operation can pass at least 1 Amp of current and/or block at least 100 volts during reverse blocking operation. Power semiconductor die are often fabricated from wide bandgap semiconductor materials, such as silicon carbide (“SiC”) or gallium nitride (“GaN”) based semiconductor materials. A wide variety of power semiconductor die are known in the art, including, for example, power Metal Oxide Semiconductor Field Effect Transistors (“MOSFETs”), power insulated gate bipolar junction transistors (“IGBTs”), power Schottky diodes, and the like. Power semiconductor die are often packaged to provide a packaged power semiconductor device.

Power MOSFETs are one widely used power semiconductor die. A power MOSFET is a three terminal device that has gate, drain and source terminals and a semiconductor layer structure that is often referred to as a semiconductor body. A source region and a drain region that are separated by a channel region are formed in the semiconductor body, and a gate electrode (which may act as the gate terminal or be electrically connected to the gate terminal) is disposed adjacent the channel region. The MOSFET may be turned on (to conduct current through the channel region between the source region and drain regions) by applying a bias voltage to the gate electrode, and may be turned off (to block current flow through the channel region) by removing the bias voltage (or reducing the bias voltage below a threshold level).

Both discrete and multichip power packaged power semiconductor devices are commercially available. Discrete power packaged power semiconductor devices include a single power semiconductor die, such as a packaged MOSFET, Schottky diode, IGBT or the like. Multichip power packaged power semiconductor devices refer to power semiconductor modules that include two or more power semiconductor dies that are provided (and typically interconnected) within a common package. Discrete packaged power semiconductor devices comprise a large segment of the power electronics industry, as they can be realized at a very low cost and easily combined to form more complex circuits.

Packaged power semiconductor devices typically generate large amounts of heat during device operation. In order to prevent this heat from damaging the device, the semiconductor die are typically attached to submounts that act as heat sinks for venting the heat from the packages. For example, copper or aluminum lead frames and/or copper covered ceramic substrates are commonly used as submounts. An upper side of the submount can be plated with nickel or silver or another metal that facilitates attaching the semiconductor die to the submount.

### SUMMARY

Pursuant to some embodiments of the present invention, packaged power semiconductor devices are provided that include a package, a power semiconductor die within the package, and a moisture barrier on an upper surface and side surfaces of an exterior of the package.

In some embodiments, the package comprises a plastic overmold. In some embodiments, the moisture barrier is directly on the plastic overmold. In some embodiments, the moisture barrier is a conformal moisture barrier that conforms to the plastic overmold. In some embodiments, the moisture barrier is further on at least part of a bottom of the exterior of the package.

In some embodiments, the semiconductor die has a first terminal and a second terminal, and the package further comprises a first lead that is electrically connected to the first terminal, the first lead extending out of the plastic overmold and a second lead that is electrically connected to the second terminal, the second lead extending out of the plastic overmold. In some embodiments, the first lead includes a widened segment that extends through an outer surface of the plastic overmold and a narrowed segment that extends outwardly from the widened segment, and the moisture barrier covers at least a portion of the widened segment.

In some embodiments, the package further comprises a submount, and the semiconductor die is mounted on an upper surface of the submount.

In some embodiments, the submount comprises a leadframe or a power substrate and the plastic overmold and the submount together encapsulate the semiconductor die.

In some embodiments, the semiconductor die further includes a third terminal that is on an opposite side of a semiconductor layer structure of the semiconductor die from the first and second terminals, and the third terminal is electrically connected to the submount.

In some embodiments, the package includes a submount and a housing, and the moisture barrier completely covers the bottom surface of the submount.

In some embodiments, the moisture barrier comprises at least one of perylene, silicone, polyurethane or an acrylic material.

In some embodiments, the moisture barrier comprises a coating having a thickness of 1-10 microns.

In some embodiments, the power semiconductor device is provided in combination with a printed circuit board, the power semiconductor device is mounted on the printed circuit board and a portion of the moisture barrier is between the package and the printed circuit board.

In some embodiments, the packaged electronic device is mounted on a metal pad on the printed circuit board, and the moisture barrier electrically insulates the semiconductor die from the metal pad.

In some embodiments, the moisture barrier is a first moisture barrier, the power semiconductor device further comprising a second moisture barrier that covers an upper surface and side surfaces of the semiconductor die. In some embodiments, the second moisture barrier further covers portions of the first and second leads.

In some embodiments, the semiconductor die is a silicon carbide based vertical MOSFET or Schottky diode.

In some embodiments, the semiconductor die is a first semiconductor die, the power semiconductor device further comprising a second semiconductor die within the package.

In some embodiments, the moisture barrier covers some but not all of the portions of the first and second leads that are external to the plastic overmold.

Pursuant to further embodiments of the present invention, power semiconductor devices are provided that include a housing, a semiconductor die having a first terminal and a second terminal, and a moisture barrier on an upper surface and side surfaces of the semiconductor die, the moisture barrier positioned between the semiconductor die and the housing.

In some embodiments, the housing comprises a plastic overmold.

In some embodiments, the housing and a submount comprise a package for the power semiconductor device, and the semiconductor die is mounted on an upper surface of the submount.

In some embodiments, the submount comprises a leadframe or a power substrate, and the plastic overmold and the submount together encapsulate the semiconductor die.

In some embodiments, the package further comprises a first lead that is electrically connected to the first terminal and a second lead that is electrically connected to the second terminal, and the moisture barrier further covers portions of the first and second leads that are within the plastic overmold.

In some embodiments, the moisture barrier directly contacts both the semiconductor die and the plastic overmold.

In some embodiments, the moisture barrier is a conformal moisture barrier that conforms to the semiconductor die.

In some embodiments, the moisture barrier and the housing are different materials.

In some embodiments, the moisture barrier is a second moisture barrier, the power semiconductor device further comprising a first moisture barrier that is on an exterior of the plastic overmold.

In some embodiments, the plastic overmold is on a top surface and side surfaces of the submount, and wherein at least a portion of a bottom surface of the submount is free of the plastic overmold.

In some embodiments, the first moisture barrier covers the bottom surface of the submount.

In some embodiments, the moisture barrier comprises at least one of perylene, silicone, polyurethane or an acrylic material.

In some embodiments, the moisture barrier comprises a coating having a thickness of 1-10 microns.

In some embodiments, the power semiconductor device is provided in combination with a printed circuit board and the power semiconductor device is mounted on the printed circuit board and a portion of the moisture barrier is between the plastic overmold and the printed circuit board.

In some embodiments, the power semiconductor device is mounted on a printed circuit board and includes a terminal that is mounted on a heat sink, and the moisture barrier electrically insulates the semiconductor die from the heat sink.

Pursuant to still further embodiments of the present invention, manufacturing methods are provided in which a semiconductor die that has a first terminal and a second terminal is packaged in a package that includes a submount and a housing to provide a preliminary power semiconductor device. A moisture barrier is formed on the preliminary power semiconductor device to form a power semiconductor device that is configured for mounting on a printed circuit board.

In some embodiments, the housing comprises a plastic overmold. In some embodiments, the moisture barrier is directly on an exterior of the plastic overmold. In some embodiments, the moisture barrier is a conformal moisture barrier that conforms to the exterior of the plastic overmold.

In some embodiments, the package further comprises a first lead and a second lead, the method further comprising electrically connecting the first lead to the first terminal, the first lead extending out of the plastic overmold and electrically connecting the second lead to the second terminal, the second lead extending out of the plastic overmold.

In some embodiments, the first lead includes a widened segment that extends through an outer surface of the plastic overmold and a narrowed segment that extends outwardly from the widened segment, and the moisture barrier covers at least a portion of the widened segment.

In some embodiments, the submount comprises a leadframe or a power substrate, and the plastic overmold and the submount together encapsulate the semiconductor die.

In some embodiments, the moisture barrier is formed to completely cover the bottom surface of the package.

In some embodiments, forming the moisture barrier comprises forming the moisture barrier via chemical vapor deposition. In some embodiments, forming the moisture barrier comprises forming the moisture barrier by dipping the preliminary power semiconductor device into a solution of a moisture barrier material. In some embodiments, forming the moisture barrier comprises spraying moisture barrier material onto the preliminary power semiconductor device.

In some embodiments, the method further comprises baking the plastic overmold at a temperature of at least 120° C. to remove moisture from the plastic overmold prior to forming the moisture barrier.

In some embodiments, the moisture barrier is formed within two hours of formation of the overmold plastic or completion of a baking process that is applied to the overmold plastic to remove moisture therefrom.

In some embodiments, the moisture barrier comprises at least one of perylene, silicone, polyurethane or an acrylic material.

In some embodiments, the moisture barrier comprises a coating having a thickness of 1-10 microns.

In some embodiments, the method further comprises mounting the power semiconductor device on a printed circuit board so that a portion of the moisture barrier is between the package and the printed circuit board.

In some embodiments, the power semiconductor device is mounted on a metal pad on the printed circuit board, and the moisture barrier electrically insulates the semiconductor die from the metal pad.

In some embodiments, the moisture barrier is a first moisture barrier, the method further comprising forming a second moisture barrier that covers an upper surface and side surfaces of the semiconductor die and portions of the first and second leads, the second moisture barrier positioned between the semiconductor die and the second portion of the package

### BRIEF DESCRIPTION OF THE DRAWINGS

FIG. 1A is a top perspective view of a discrete packaged power semiconductor device according to embodiments of the present invention.

FIG. 1B is a perspective view of the discrete packaged power semiconductor device of FIG. 1A with a moisture barrier and overmold package thereof removed.

FIG. 1C is a schematic cross-sectional view of the discrete power semiconductor electronic device of FIG. 1A.

FIG. 2 is a schematic cross-sectional view of a packaged power semiconductor device according to further embodiments of the present invention that includes a power substrate.

FIG. 3 is a schematic side cross-sectional view of a packaged power semiconductor device according to additional embodiments of the present invention where the moisture barrier fully encapsulates the submount.

FIG. 4A is a schematic cross-sectional view of a packaged power semiconductor device according to still further embodiments of the present invention that includes an internal moisture barrier.

FIG. 4B is a schematic cross-sectional view of a modified version of the packaged power semiconductor device of FIG. 4A that further includes an external moisture barrier.

FIGS. 5-7 are schematic side cross-sectional views of packaged power semiconductor devices according to further embodiments of the present invention.

FIG. 8 is a flow chart of a method of fabricating a packaged power semiconductor device according to embodiments of the present invention.

Note that when multiple like elements are shown in the figures, they may be identified using two-part reference numerals. Such elements may be referred to herein individually by their full reference numeral (e.g., floating lead 136-1) and may be referred to collectively by the first part of their reference numeral (e.g., the floating leads 136).

### DETAILED DESCRIPTION

Power semiconductor devices are designed to block high voltages during reverse blocking operation and to pass high current levels during on-state operation. For example, a power semiconductor device may need to block hundreds or thousands of volts and/or pass tens or hundreds of amperes. Operation at these voltage and current levels may generate significant heat within the power semiconductor die. Because of the high heat levels, many discrete power semiconductor devices are packaged in ceramic air cavity packages in which the power semiconductor die is mounted on a metal submount and enclosed within an air cavity in a ceramic housing (these packages are referred to as ceramic air cavity packages). The ceramic housing and metal submount can withstand the heat generated by the power semiconductor die during operation and can efficiently dissipate this heat. However, the use of ceramic air cavity packages increase both the size and cost of the packaged power semiconductor device.

Most semiconductor devices that operate at low power levels are packaged by encapsulating the semiconductor die in a plastic overmold. In recent years, plastic overmold encapsulations have been developed that are suitable for use with power semiconductor devices. When plastic overmold encapsulations are used, the semiconductor die is typically mounted on a submount and leads are electrically connected to corresponding terminals on the semiconductor die. A plastic overmold material such as, for example, an epoxy molding compound, is then injection-molded to encapsulate the power semiconductor die and at least part of the submount. The leads extend through the plastic overmold encapsulation so that electrical connections may be made between the semiconductor die and external devices (e.g., inputs, outputs, bias voltage sources, etc.). The submount, leads and plastic overmold encapsulation together comprise the package for the power semiconductor die.

Discrete packaged power semiconductor devices are typically mounted on a printed circuit board of a larger electronic system. Unfortunately, standard epoxy molding compounds are susceptible to moisture absorption from the environment. This moisture absorption may primarily be in the form of direct diffusion of moisture through the epoxy resin. Moisture absorption into a plastic overmold encapsulated power semiconductor die can be problematic. In particular, the moisture that is absorbed within the plastic overmold will expand during the soldering reflow process used to attach the discrete power semiconductor device to the printed circuit board of the larger electronic system. As the plastic overmold expands it may delaminate from the semiconductor die. In some cases, the plastic overmold may instead crack or even explode. Generally speaking, delamination of the overmold encapsulation may lead to premature device failure (for example, as the device undergoes thermal cycling during normal operation the delamination may increase, which may weaken or break the connections between the power semiconductor die terminals and the package leads), while cracking (or exploding) of the plastic overmold typically results in immediate device failure.

In order to reduce the likelihood that moisture absorption can result in device failure, plastic overmold encapsulated power semiconductor devices may be rated based on an industry standardized moisture sensitivity scale that has been promulgated by IPC International, which is a global association of entities involved in electronics manufacturing. This moisture sensitivity scale is set forth in document IPC/JEDEC J-STD-033. Document IPC/JEDEC J-STD-033 specifies eight different moisture sensitivity levels and, for each level, specifies a maximum length of time that a packaged semiconductor device may be maintained outside of a moisture barrier bag before the device is soldered to a printed circuit board. For example, an electronic device with an IPC/JEDEC J-STD-033 moisture sensitivity rating level of “3” should not be maintained outside of a moisture barrier bag for more than one week at a temperature of less than 30° C. and a relative humidity of less than 60% per the IPC/JEDEC J-STD-033 standard before being soldered to a printed circuit board to ensure that the device will not have a heightened risk of moisture-induced failure.

Higher moisture sensitivity rating levels may severely limit the time that an electronic device may be outside of a moisture barrier bag before the device is soldered to the printed circuit board of a larger system. For example, electronic devices having an IPC/JEDEC J-STD-033 moisture sensitivity rating level of “5a” can only be maintained outside of a moisture barrier bag for 24 hours. Electronics manufacturers that assemble electronic devices that include discrete packaged power semiconductor devices must take the moisture sensitivity rating levels of the discrete packaged power semiconductor devices into account during the fabrication process to ensure that the devices are not subjected to excessive moisture absorption that can result in damage to, or destruction of, the packaged power semiconductor device, particularly during the solder reflow operation. This may complicate the fabrication process, and increases the risk that a larger electronic system may prematurely fail due to a moisture absorption induced failure of a power semiconductor device included in the larger electronic system.

Pursuant to embodiments of the present invention, packaged power semiconductor devices are provided that include a package and a separate moisture barrier. The overmold encapsulation may be formed of a plastic material such as, for example, an epoxy molding compound. The moisture barrier may be conformally coated on the plastic overmold encapsulation. As is known in the art, a conformal coating refers to a layer of material that is coated (e.g., formed or deposited) on a surface of an underlying structure that generally conforms to or “tracks” the shape of the surface of the underlying structure. Conformal coatings have a generally uniform thickness (e.g., variation of less than 10-15% for portions that are on flat surfaces of the underlying structure, although slightly larger variation may occur at corners or other non-planar regions). The moisture barrier may comprise any material that significantly or completely prevents moisture ingress into the overmold encapsulation. For example, acrylic materials, polyurethanes, silicones and/or parylene are all materials that may be conformally formed or deposited as a coating that will act as such a moisture barrier. The moisture barrier may be formed, for example, on the plastic overmold encapsulation by automated spaying, dipping, a condensation process or chemical vapor deposition. Adding this moisture barrier to a packaged power semiconductor device may significantly extend the time that the device may remain outside of a moisture barrier bag before the device is soldered to a customer printed circuit board. The moisture barrier may also decrease the possibility of moisture-induced device failure during normal operation of the device. The moisture barrier may be applied directly after formation of the plastic overmold encapsulation (e.g., following a baking operation that is used to cure the plastic overmold), or during a later processing step. The packaged power semiconductor device may optionally be subjected to a slow baking operation that is designed to remove moisture from the device prior to application of the moisture barrier.

In some embodiments, the moisture barrier may be applied to substantially or completely cover the plastic overmold encapsulation material. Herein, references to “substantially” mean within +/−10%. The moisture barrier may not be applied, or may only be partially applied, to exposed metallic elements of the packaged power semiconductor device that are designed to be soldered to external elements such as metal pads. In other embodiments, the moisture barrier may completely encapsulate the entire body of the packaged power semiconductor device, and only distal portions of the leads may be free of the moisture barrier. In such embodiments, the moisture barrier may be part of the primary heat dissipation path from the semiconductor die to an external heatsink such as a heatsink that is surface mounted on a customer printed circuit board. The moisture barrier may be sufficiently thin so as to have good thermal conductivity while also electrically isolating the packaged power semiconductor device from the heat sink.

As noted above, the package leads of a plastic overmold encapsulated packaged power semiconductor device extend through the plastic overmold so that each lead has an encapsulated segment and an exposed segment. In some embodiments, the moisture barrier may extend onto the portions of the exposed segments of the leads that are adjacent the plastic overmold encapsulation. This may help ensure that the leads themselves do not provide a path for moisture ingress within the overmold encapsulation. Additionally, as will be discussed below, the moisture barrier may advantageously increase the “creepage distance” between adjacent leads, which may improve device performance.

While the above-described moisture barriers are provided on the exterior surface of the plastic overmold encapsulation (e.g., conformally formed thereon), the teachings of the present invention are not limited thereto. For example, in other embodiments, a moisture barrier may be formed on the semiconductor die, submount and leads (and possibly bond wires) after the leads are electrically connected to the terminals of the semiconductor die, but before the plastic overmold is formed to encapsulate the semiconductor die. In such embodiments, the moisture barrier will be between the semiconductor die and the plastic overmold encapsulation. This “internal” moisture barrier may be provided as a standalone moisture barrier or may be combined with the above-described moisture barriers that are formed on the exterior surface of the plastic overmold encapsulation.

Embodiments of the present invention will now be discussed in further detail with reference to the attached figures. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other packaged electronic devices such as IGBTs, Schottky diodes, gate-controlled thyristors and the like.

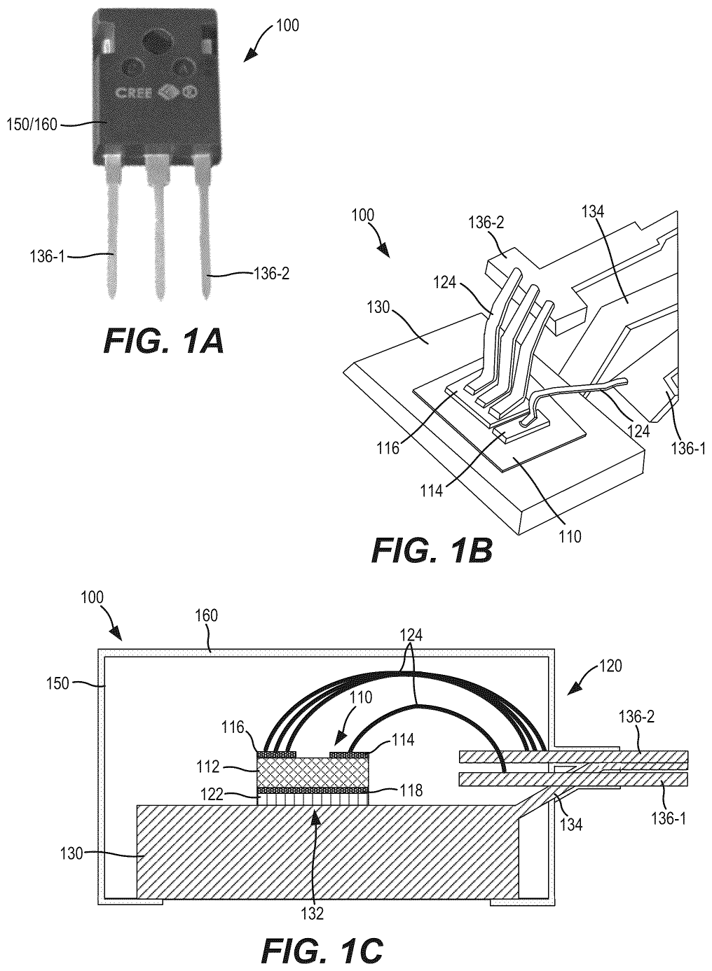

FIGS. 1A-1C schematically illustrate a packaged power semiconductor device according to certain embodiments of the present invention. In particular, FIG. 1A is a top perspective view of the packaged power semiconductor device 100, FIG. 1B is a perspective view of the packaged power semiconductor device 100 with a moisture barrier and plastic overmold thereof removed, and FIG. 1C is a schematic side cross-sectional view of the device 100.

Referring FIGS. 1A-1C, the packaged power semiconductor device 100 includes a power semiconductor die 110 that is mounted on an upper surface of a submount, where the submount in this embodiment comprises a lead frame 130. The power semiconductor die 110 may be a semiconductor device that is designed to block high voltage levels (e.g., hundreds of volts or more) and/or to carry large currents. The power semiconductor die 110 may include a semiconductor layer structure that is formed using, for example, silicon and/or wide bandgap semiconductor materials such as silicon carbide and/or gallium nitride-based and/or aluminum nitride-based semiconductor systems (e.g., GaN, AlGaN, InGaN, AlN, etc.). Other wide bandgap materials may be used such as devices formed in other Group III-V semiconductor systems or in Group II-VI semiconductor systems. The power semiconductor die 110 may comprise, for example, a MOSFET, a MISFET, an IGBT, a Schottky diode, a gate-controlled thyristor, etc. The power semiconductor die 110 may have a vertical structure in which the upper side of the die includes at least one terminal and the lower side of the die 110 also includes at least one terminal.

In the depicted embodiment, the power semiconductor die 110 is a discrete power MOSFET that has a vertically extending drift region through which current flows during on-state operation. As shown in FIG. 1C, the MOSFET includes a semiconductor layer structure 112. The semiconductor layer structure 112 may be formed of wide band-gap semiconductor materials such as, for example, silicon carbide. A gate terminal 114 and a source terminal 116 are provided on an upper surface of the semiconductor layer structure 112, and a drain terminal 118 is located on a lower surface of the semiconductor layer structure 112. Each of the terminals 114, 116, 118 may be implemented as an exposed metal pad. Typically, the gate terminal/pad 114 is smaller than the source terminal/pad 116, and the drain terminal 118 may be about the same size as, or larger than, the source terminal/pad 116. Since the source and drain terminals 116, 118 are on opposed sides of the semiconductor layer structure 112, the MOSFET 110 is a vertical device.

The lead frame 130 includes a die attach region 132 on an upper surface thereof and an integrated lead 134. A bottom surface of the MOSFET 110 may be attached to the die attach region 132 of the lead frame 130 using any appropriate bonding material or technique. In the depicted embodiment, the MOSFET 110 is bonded to the lead frame 130 using a die attach material 122. The drain terminal 118 of MOSFET 110 is electrically connected to the integrated lead 134 through the die attach material 122 and the lead frame 130. A pair of floating leads 136-1, 136-2 are provided, and one or more bond wires 124 physically and electrically connect the gate and source terminals 114, 116 on the upper side of the MOSFET 110 to the respective floating leads 136-1, 136-2. In the depicted embodiment, a single bond wire 124 connects the gate terminal 114 to floating lead 136-1, while three bond wires 124 connect the source terminal 116 to floating lead 136-2. It should be noted that herein the term “bond wire” is used broadly to cover traditional bond wires as well as other functionally equivalent structures such as ribbons or clips that may be used instead of true wires.

A plastic overmold encapsulation 150 encapsulates the power semiconductor die 110 and at least an upper surface of the lead frame 130, as well as at least a portion of each side surface of the lead frame 130. The leads 134, 136 extend through the plastic overmold encapsulation 150 so that each lead 134, 136 has a first segment that is within the plastic overmold encapsulation 150 and a second segment that is outside of the plastic overmold encapsulation 150. The plastic overmold encapsulation 150 covers and protects the MOSFET 110. While embodiments of the present invention will primarily be described with respect to devices that include an epoxy molding compound as an overmold encapsulation, it will be appreciated that embodiments of the present invention are not limited thereto. For example, in other embodiments the encapsulation may comprise a silicone gel or another compound. The encapsulation 150 may hold the floating leads 136 in their proper location.

The lead frame 130, leads 134, 136 and the overmold encapsulation 150 together form a package 120 for the power semiconductor die 110. While one integrated lead 134 and two floating leads 136 are provided, it will be appreciated that embodiments of the present invention are not limited thereto. For example, three floating leads 136 and no integrated leads 134 may be provided in other embodiments. It will also be appreciated that multiple leads may be provided for one or more of the terminals 114, 116, 118 of the power semiconductor die 110. For example, the source and/or drain terminals 116, 118 may each be connected to two leads. It will also be appreciated that the number of terminals and/or the number of leads may be varied depending upon the type of semiconductor die 110. For example, a Schottky diode only includes two terminals (an anode terminal and a cathode terminal) and hence only two leads may be provided for a packaged Schottky diode. The floating leads 136 may initially be integral with the lead frame 130, but may be separated from the lead frame 130 during the fabrication process and may be held in place by the overmold encapsulation 150.

As can best be seen in FIG. 1C, a moisture barrier 160 is provided on an exterior surface of the plastic overmold encapsulation 150. The moisture barrier 160 may be formed after the overmold encapsulation 150 is formed and cured. The moisture barrier 160 may be formed conformally on the plastic overmold encapsulation 150 in some embodiments. The plastic overmold encapsulation 150 may comprise a rigid material that protects the MOSFET 110 during handling. The moisture barrier 160, in contrast, may be a less rigid material that that significantly or completely prevents moisture ingress into the overmold encapsulation and that has good coating properties, so that a continuous coating may be applied that presents a barrier for moisture ingress into the plastic overmold encapsulation 150. In example embodiments, the moisture barrier may comprise an acrylic material, a polyurethane material, a silicone material and/or a parylene material. All of these materials may be conformally formed or deposited as a coating and will significantly or completely prevents moisture ingress into the overmold encapsulation.

The moisture barrier 160 may comprise a thin layer that may be formed/deposited on the exterior surface of the plastic overmold encapsulation 150 and, optionally, on selected portions of the parts of the leadframe 130 and/or leads 134, 136 that extend outside the overmold encapsulation 150. For example, as shown in FIG. 1C, the moisture barrier 160 may extend onto some or all of the side surfaces of the lead frame 130. The moisture barrier 160 may also extend partially onto the portion of each lead 134, 136 that extends out of the overmold encapsulation 150. In example, embodiments, the moisture barrier 160 may have a thickness of between 1-10 microns. The moisture barrier 160 may be conformally coated onto the plastic overmold encapsulation in some embodiments.

The moisture barrier 160 may be formed, for example, on the plastic overmold encapsulation 150 by a spraying or sputtering process. For example, the moisture barrier may be sprayed in liquid form onto the overmold encapsulation 150 using an automated spraying process that ensures a substantially consistent thickness of the moisture barrier coating (it should be noted that variation of the thickness of the coating at the corners should be expected), and the material may be cured to form the moisture barrier 160. Alternatively, after the plastic overmold encapsulation 150 is formed, the packaged electronic device 100 may be dipped into a vat of moisture barrier material to form the moisture barrier 160. The packaged power semiconductor device 100 may be held by one or more of the leads 134, 136 during this dipping process, as the distal ends of the leads 134, 136 are typically not coated with the moisture barrier 160 so that the leads 134, 136 may be connected to external devices (e.g., by bond wires).

In still other embodiments, the moisture barrier 160 may be formed by a chemical deposition process. In particular, after the plastic overmold encapsulation 150 is formed (including curing), the packaged power semiconductor device 100 may be placed in a chemical vapor deposition chamber and the source material for the moisture barrier 160 may be injected into the chamber in gaseous form. The packaged power semiconductor device 100 may be positioned in another portion of the chamber that is at a lower temperature and/or pressure, and the gaseous material may condense onto the exterior surface of the packaged power semiconductor device 100 to form the moisture barrier 160. During any of the above-discussed fabrication processes, portions of the packaged power semiconductor device 100 that should not have the moisture barrier applied thereto may be covered with a mask (e.g., Kapton tape, photoresist, etc.). The mask may later be removed with any moisture barrier material that is deposited on the mask. In other cases, fixtures may be provided that act as a mask. For example, when chemical vapor deposition is used to form the moisture barrier 160, a fixture may be provided in the chemical vapor deposition chamber that includes openings that snugly receive respective ends of the leads 134, 136 of the packaged power semiconductor device 100. The packaged power semiconductor device 100 may be mounted in the chamber by inserting the ends of the leads 134, 136 into the fixture. All portions of the packaged power semiconductor device 100 except for the leads 134, 136 will thus be exposed, and the moisture barrier 160 may be formed by chemical vapor deposition to coat the entirety of the exterior of the packaged power semiconductor device except for the ends of the leads 134, 136.

The moisture barrier 160 may be applied directly after formation (including curing) of the plastic overmold encapsulation 150. This may help ensure that moisture does not seep into the plastic overmold encapsulation 150 prior to formation of the moisture barrier 160. The packaged power semiconductor device 100 may optionally be subjected to a slow baking operation that is designed to remove moisture from the device 100 prior to application of the moisture barrier 160. For example, the packaged power semiconductor device 100 may be baked at a temperature of 125° C. for at least eight hours to remove moisture therefrom, and then the moisture barrier 160 may be formed on the overmold encapsulation 150. Alternatively, the packaged power semiconductor device 100 may be baked for longer times at lower temperatures or for shorter times at higher temperatures. Generally speaking, the longer the baking operation and the higher the temperature, the greater the capability of the baking operation to remove any moisture that is present within the device. The slow bake may be performed, for example, if the moisture barrier 160 is not applied shortly after formation of the overmold encapsulation 150.

It will be appreciated that the above-discussed materials that may be used to form the moisture barrier 160 and the techniques for forming the moisture barrier 160 that are discussed above may be used to form any of the moisture barriers discussed below that are included in packaged power semiconductor devices according to embodiments of the present invention.

As shown in FIG. 1C, the leads 134, 136 extend through the plastic overmold encapsulation 150 so that each lead 134, 136 has an encapsulated segment and an exposed segment. In some embodiments, the moisture barrier 160 may extend onto the portions of the exposed segments of the leads 134, 136 that are adjacent the plastic overmold encapsulation 150. This may help ensure that the leads 134, 136 themselves do not provide a path for moisture ingress within the overmold encapsulation 150. Additionally, the moisture barrier 160 may advantageously increase the “creepage distance” between adjacent leads, which refers to the shortest distance along a surface of a dielectric material between two conductive parts. Here, the creepage distance is the distance between the exposed portions of adjacent leads 134, 136 along a surface of an intervening dielectric material. Since the moisture barrier 160 covers a portion of the leads 134, 136, the creepage distance is increased. This may allow the packaged power semiconductor device 100 to be rated for higher operating voltages and/or allow for operation of the device in higher pollution environments.

As the above discussion makes clear, the packaged power semiconductor device 100 includes a semiconductor die 110 having at least a first terminal 114 and a second terminal 116. A package that comprises a plastic overmold 150 at least partially covers the semiconductor die 110. The package may also include a first lead 136-1 that is electrically connected to the first terminal 114 and a second lead 136-2 that is electrically connected to the second terminal 116. The first and second leads 136-1, 136-2 each extend out of the plastic overmold 150. A moisture barrier 160 is on an upper and side surfaces of the plastic overmold 150.

The moisture barrier 160 may be directly on the upper surface, side surfaces and bottom surface of the overmold package 150 in some embodiments. In some embodiments, the first and second terminals 114, 116 may be on a first surface of a semiconductor layer structure 112 of the semiconductor die 110, and the semiconductor die 110 may further include a third terminal 118 that is on an opposite side of the semiconductor layer structure 112 from the first and second terminals 114, 116. The package 120 may also include a submount 130, and the semiconductor die 110 may be mounted on an upper surface of the submount 130. In some embodiments, the moisture barrier 160 may completely cover a bottom surface of the package 120.

In some embodiments, the moisture barrier 160 comprises at least one of parylene, silicone, polyurethane or an acrylic material, and/or the moisture barrier 160 may have a thickness of between 1-10 microns. As shown in FIGS. 1A-1B, in some embodiments, the first lead 136-1 may include a widened segment that extends through an outer surface of the overmold package 150 and a narrowed segment that extends outwardly from the first widened segment, and the moisture barrier 160 may covers at least a portion of the widened segment.

In some embodiments, the packaged electronic device 100 may be mounted on a printed circuit board such as a customer printed circuit board, and a portion of the moisture barrier 160 may be between the overmold package 150 and the printed circuit board. For example, the packaged electronic device 100 may be mounted on a metal pad on the customer printed circuit board (e.g., using screws or clips), and the moisture barrier 160 may electrically insulate the semiconductor die 110 from the metal pad.

As noted above, packaged power semiconductor devices such as device 100 are typically mounted on printed circuit boards of larger electronic systems. These larger printed circuit boards are often referred to as customer motherboards. The packaged power semiconductor device 100 would typically be mounted on a heat sink on the customer motherboard so that heat vented through the primary thermal interface of the packaged power semiconductor device 100 (here, the path through the drain terminal 118 and the lead frame 130) may also be vented away from the customer motherboard. In many cases, the heat sink I surface mounted on the customer motherboard. In some cases, an exposed metal portion of the packaged power semiconductor device 100 (e.g., the bottom surface of the submount 130) may be mounted on the heatsink. In some cases, the leads 134, 136 of the packaged power semiconductor device 100 may be mounted in respective plated through holes of the customer motherboard. In some cases, the exposed metal portion of the packaged power semiconductor device 100 may be mounted on the heatsink and the leads 134, 136 may also be mounted in respective plated through holes of the customer motherboard.

As can be seen from FIG. 1C, the primary thermal interface may not be electrically isolated from the power semiconductor die 110, as the drain terminal 118 is electrically connected to the bottom of the lead frame 130. It is often necessary to electrically isolate the semiconductor die 110 from the heat sink on the customer motherboard. This can be accomplished by interposing a so-called “thermal pad” in the form of a thin dielectric layer (e.g., a silicone layer) between the packaged power semiconductor device 100 and the heat sink on the customer motherboard that electrically isolates the power semiconductor die 110 from the heat sink. The packaged power semiconductor device may be mechanically attached to the customer motherboard (e.g., a heatsink for the motherboard) with the thermal pad therebetween using, for example, screws or spring clips, and the device leads may be soldered to the motherboard. Electrically isolating the power semiconductor die 110 from the customer motherboard using such a thermal pad is acceptable and convenient for packaged semiconductor devices that operate at lower voltage (e.g., tens of volts) and current levels. However, with power semiconductor devices that are designed to block many hundreds or even thousands of volts, the capacitive coupling across the thermal pad may be strong enough to negatively impact the performance of the semiconductor device and/or degrade the material of the thermal pad, which may result in a short circuit between the primary thermal interface and the metal pad on the customer motherboard. Such a short circuit will typically render the packaged power semiconductor device inoperable, and may also damage or even destroy the device

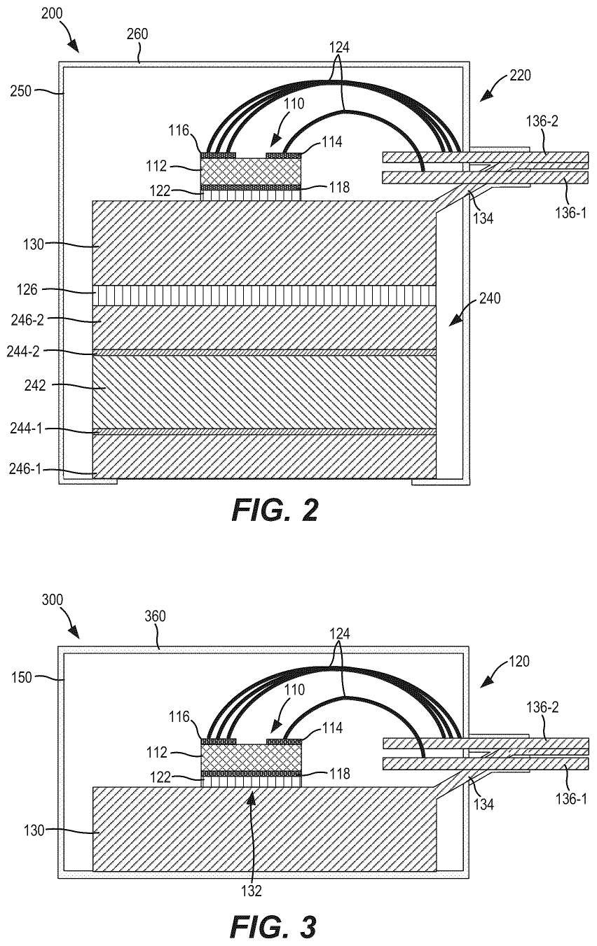

FIG. 2 is a schematic cross-sectional view of a discrete packaged power semiconductor device 200 according to further embodiments of the present invention. The packaged power semiconductor device 200 is similar to the packaged power semiconductor device 100 discussed above with reference to FIGS. 1A-1C, but further includes a power substrate 240. As will be discussed below, the power substrate 240 includes an insulating substrate that electrically isolates the power semiconductor die 110 from the customer motherboard.

As can be seen by comparing FIGS. 1C and 2, the only differences between packaged power semiconductor device 200 and packaged power semiconductor device 100 are that packaged power semiconductor device 200 further includes (1) the power substrate 240 that is attached to the bottom surface of the lead frame 130, and (2) the plastic overmold 250 and the moisture barrier 260 extend to cover side surfaces of the power substrate 240. Accordingly, elements of packaged power semiconductor device 200 that are identical or substantially identical to corresponding elements of packaged power semiconductor device 100 are labelled using the same reference numerals as are used in FIGS. 1A-1C, and further description of these like elements will therefore generally be omitted. The same convention applies throughout the present application.

As shown in FIG. 2, the power substrate 240 includes a ceramic substrate 242. A lower metal cladding layer 246-1 is formed on the lower side of the ceramic substrate 242, and an upper metal cladding layer 246-2 is formed on the upper side of the ceramic substrate 242. The lead frame 130 is mounted on the upper metal cladding layer 246-2 using a substrate attach material 126. As used herein, the term “power substrate” refers to a dielectric substrate that has a metal cladding layer on both sides thereof. There are two primary types of power substrates. The first type is known as an Active Metal Brazed (“AMB”) power substrate, which includes first and second metal braze layers 244-1, 244-2 that are used to bond the first and second metal cladding layers 246-1, 246-2, respectively, to the ceramic substrate 242. In contrast to soldering, brazing can be used to bond metals to dielectric surfaces. The metal braze material has some similarities to solder, but the bonding process is performed at higher temperatures and most typically in a vacuum. The resulting bond is high in reliability as compared to conventional solder attachment. The second type of power substrate is referred to as a Direct Bonded Substrate (or, more typically, a Direct Bonded Copper or “DBC” power substrate, as the metal cladding layers 246-1, 246-2 are typically copper layers). DBC power substrates are formed by pressing the metal cladding layers 246-1, 246-2 directly against the dielectric substrate 242 while being heat treated in a controlled atmosphere. DBC power substrates are not as reliable as AMB power substrates.

The plastic overmold 250 differs from plastic overmold 150 in that plastic overmold 250 extends to cover side surfaces of the power substrate 240. The moisture barrier 260 is conformally coated on plastic overmold 250 and on selected portions of the power substrate 240 and the leads 134, 136. The lead frame 130, the leads 134, 136, the power substrate 240, and the plastic overmold 250 form a package 220 for the power semiconductor die 110. The moisture barrier 260 protects the package 220 from moisture ingress. The power substrate 240 serves as the primary thermal interface for venting heat that is generated in the power semiconductor die 110 from the device package 220.

While packaged power semiconductor device 200 includes both a lead frame 130 and a power substrate 240, it will be appreciated that the lead frame 130 may be omitted in other embodiments, and the integrated lead 134 of the lead frame replaced with a third floating lead 136. In such embodiments, the power semiconductor die 110 may be mounted directly on the upper cladding layer 246-2 via a die attach material 122.

The packaged power semiconductor devices 100, 200 of FIGS. 1A-1C and 2 include moisture barriers 160, 260 that do not cover the majority of the exposed bottom surface of the submount 130, 240. FIG. 3 is a schematic side cross-sectional view of a discrete packaged power semiconductor device 300 according to additional embodiments of the present invention that includes a moisture barrier 360 that fully covers the exposed bottom surface of the submount 130.

As can be seen by comparing FIGS. 1C and 3, the packaged power semiconductor device 300 may be identical to the packaged power semiconductor device 100 except that packaged power semiconductor device 300 includes a moisture barrier 360 that extends to substantially or fully cover the bottom surface of the lead frame 130. Thus, the moisture barrier 360 may completely encapsulate the entire body of the package 120 so that only distal portions of the leads 134, 136 may be free of the moisture barrier 360. The moisture barrier 360 may be part of a heat dissipation path from the semiconductor die 110 to an external heatsink such as a heatsink on a customer printed circuit board. Since the moisture barrier 360 fully encapsulates the lead frame 130 (other than the integrated lead 134), it electrically isolates the packaged electronic device 300 from a printed circuit board or heat sink (not shown) on which the packaged electronic device 300 is mounted. Moreover, since the moisture barrier 360 may be very thin, it may exhibit good thermal conductivity and hence not interfere with the heat dissipation path which will extend through the moisture barrier 360. In some embodiments, the moisture barrier 360 may eliminate any need for a thermal pad between the packaged power semiconductor device and the heat sink, while also eliminating any need for including a power substrate in the packaged power semiconductor device. In other words, in some embodiments, a lead frame of the packaged power semiconductor device may be directly attached to a heat sink without any intervening thermal pad as the moisture barrier 360 may electrically isolate the lead frame 130 from the customer motherboard/heat sink.

While packaged power semiconductor device 300 includes a lead frame 130, it will be understood that it could also include a power substrate 240 (as is the case in packaged power semiconductor device 200 of FIG. 2) or that it could include a power substrate that replaces the lead frame 130.

As discussed above, packaged power semiconductor devices that include plastic overmold encapsulations may be particularly susceptible to moisture related damage during the solder reflow process that is often used to mount the device to a customer printed circuit board. As described above, if moisture builds up within the plastic overmold may result in delamination of the plastic overmold from the semiconductor die, or in cracking of the plastic overmold encapsulation. Additionally, much smaller amounts of moisture can also cause problems if the moisture penetrates into the power semiconductor die. While power semiconductor die typically include passivation layers that act as moisture barriers, the top surface of most power semiconductor die comprise metal bond pads that act as terminals of the device. The passivation layer(s) will not cover these pads so that bond wires or leads may be soldered to the pads. The seams between the metal bond pads and the passivation on the top surface of the semiconductor die may be susceptible to moisture ingress.

While the above-described moisture barriers 160, 260, 360 are provided on the exterior surface of the plastic overmold encapsulation (e.g., conformally formed thereon), the teachings of the present invention are not limited thereto. In particular, pursuant to further embodiments of the present invention, packaged power semiconductor devices are provided which include an internal moisture barrier that is conformally coated onto the semiconductor die and submount after electrical connections are made to the terminals of the power semiconductor die but prior to application of a plastic overmold encapsulation. The internal moisture barrier may be positioned between the power semiconductor die and the overmold encapsulation.

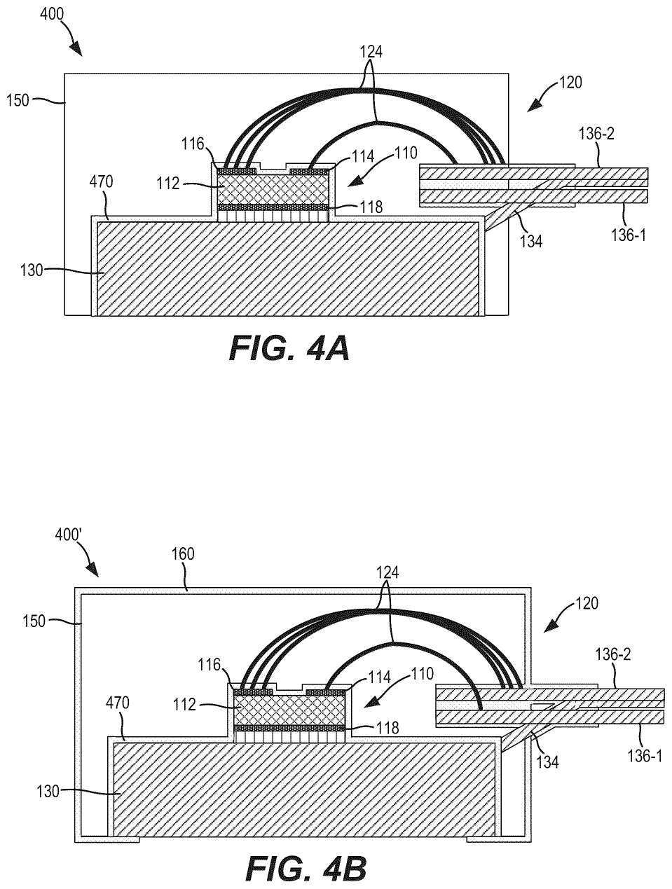

FIG. 4A is a schematic side cross-sectional view of a packaged power semiconductor device 400 according to further embodiments of the present invention that includes such an internal moisture barrier 470. As shown in FIG. 4A, packaged power semiconductor device 400 may be very similar to the packaged power semiconductor device 100 discussed above with reference to FIGS. 1A-1C. Packaged power semiconductor device 400 differs from packaged power semiconductor device 100 in two ways. First, packaged power semiconductor device 400 does not include the external moisture barrier 160 that is included in packaged electronic device 100. Second, packaged power semiconductor device 400 includes an internal moisture barrier 470 that is conformally coated directly on the semiconductor die 110, the lead frame 130, the bond wires 124, and on portions of the leads 134, 136. The internal moisture barrier 470 is formed after the power semiconductor die 110 is attached to the lead frame 130 and the wire bonds 124 are bonded to the terminals 114, 116 and the floating leads 136. As such, the internal moisture barrier 470 will not negatively affect electrical connections within the device 400. The internal moisture barrier 470 may completely coat the upper surface and the side surfaces of the power semiconductor die 110. The internal moisture barrier 470 may also coat some or all of the upper surface and/or the side surfaces of the lead frame 130. The internal moisture barrier 470 may also coat portions of the leads 134, 136 and the bond wires 124 (the internal moisture barrier coating the bond wires 124 is not shown in FIGS. 4A-4B).

The packaged power semiconductor device 400 thus includes a semiconductor die 110 having a first terminal 114 and a second terminal 116, a first lead 136-1 that is electrically connected to the first terminal 114 and a second lead 136-2 that is electrically connected to the second terminal 116, an internal moisture barrier 470 that covers an upper surface and side surfaces of the semiconductor die 110 and portions of the first and second leads 136-1, 136-2, and a plastic overmold 150 that covers the internal moisture barrier 470. The internal moisture barrier 470 may be a conformal internal moisture barrier 470 in some embodiments.

FIG. 4B is a schematic cross-sectional view of a modified version 400′ of the packaged power semiconductor device 400 of FIG. 4A. The packaged power semiconductor device 400′ is identical to the packaged power semiconductor device 400 except that device 400′ further includes the external moisture barrier 160 that is discussed above with reference to FIGS. 1A-1C. Thus, further description of packaged power semiconductor device 400′ will be omitted.

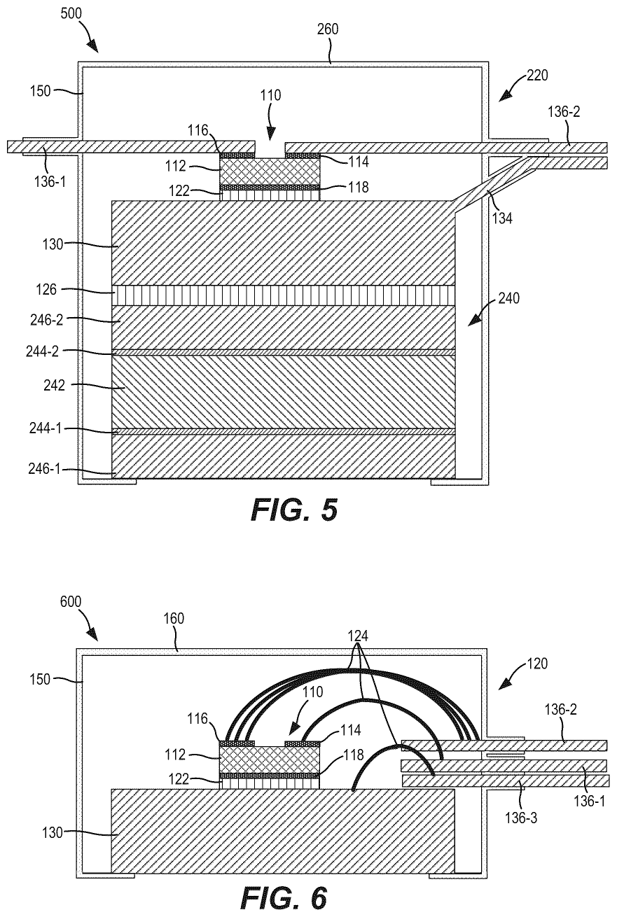

FIG. 5 is a schematic side cross-sectional view of a packaged power semiconductor device 500 according to further embodiments of the present invention. The packaged power semiconductor device 500 is similar to packaged power semiconductor device 200, except that the leads 136-1, 136-2 are directly soldered to the respective terminals 114, 116, thereby eliminating any need for bond wires. Leads 136-1 and 136-2 are shown as extending from different sides of the device 500 so that both leads can better be seen in the cross-sectional view of FIG. 5. It will be appreciated that any of the embodiments of the present invention discussed herein may have such direct soldered leads that are used in place of floating leads 136 that are physically and electrically connected to the terminals 114, 116 through bond wires 124.

FIG. 6 is a schematic side cross-sectional view of a packaged power semiconductor device 600 according to further embodiments of the present invention. The packaged power semiconductor device 600 is similar to packaged power semiconductor device 100, except that the integrated lead 134 is replaced with a third floating lead 136-3. The electrical connection between the drain of power semiconductor die 110 and the third floating lead 136-3 is through the drain terminal 118, the die attach material 122, the lead frame 130 and a bond wire 124. It will be appreciated that any of the embodiments of the present invention discussed herein may have the lead arrangement shown in FIG. 6.

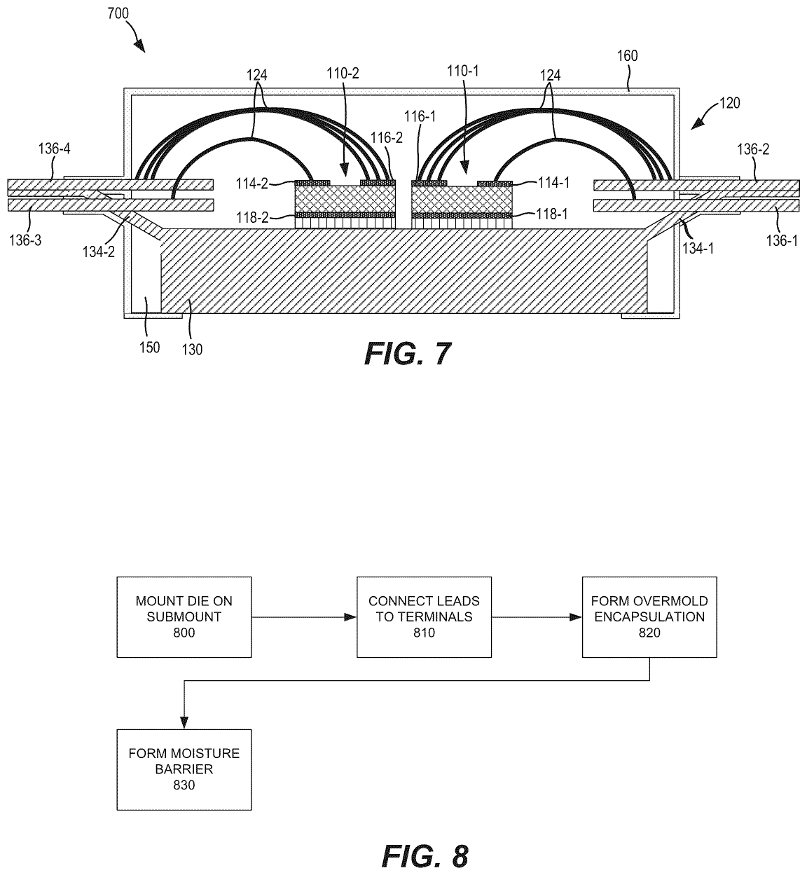

While embodiments of the present invention have primarily been discussed with reference to discrete packaged power semiconductor devices that include a single semiconductor die 110, it will be appreciated that embodiments of the present invention are not limited thereto. For example, FIG. 7 illustrates a packaged power semiconductor device 700 in the form of a power semiconductor module that includes two power semiconductor die 110-1, 110-2. In an example embodiment, the two power semiconductor die 110-1, 110-2 may be power MOSFETs that are electrically connected, for example, in series or in parallel. As shown in FIG. 7, a pair of floating gate leads 136-1, 136-2 are electrically connected to the gate terminals 114-1, 114-2 of the respective power semiconductor die 110-1, 110-2 by bond wires 124 (in other embodiments, both gate terminals 114 could be connected to a single floating gate lead 136). The source terminals 116-1, 116-2 of each die 110 may be connected to one or more floating source leads 136. The drain terminals 118-1, 118-2 are connected to respective integrated drain leads 134-1, 134-2 (in other embodiments, a single drain lead 134 may be provided that is electrically connected to the drain terminals of both power semiconductor die 110-1, 110-2). The power semiconductor die 110-1, 110-2 are encapsulated in an overmold package 150, and a moisture barrier 160 (e.g., a conformal moisture barrier 160) covers at least the upper surface and side surfaces of the plastic overmold encapsulation 150. The moisture barrier 160 may also extend partially onto (or may completely cover) the bottom surface of the plastic overmold 150. Thus, it will be appreciated that the moisture barriers according to embodiments of the present invention can also be applied to multichip modules. It will also be appreciated that the multichip modules may alternatively or additionally include the internal moisture barrier 470 discussed above with reference to FIGS. 4A-4B.

It will be appreciated that when multiple power semiconductor die 110 are included in a packaged power semiconductor device according to embodiments of the present invention, the semiconductor die 110 may the same or different, and may be electrically connected to each other and to the leads 134, 136 of the package in a variety of ways. Thus, in example embodiments, multiple power MOSFETs may be provided that are connected in series or parallel, multiple power Schottky diodes may be provided that are connected in series or parallel, one or more power MOSFETs and one or more power Schottky diodes may be connected in series or parallel, etc.

FIG. 8 is a flow chart of a method of fabricating a packaged power semiconductor device according to embodiments of the present invention. As shown in FIG. 8, operations may begin with a semiconductor die having a first terminal and a second terminal being mounted on a submount (Block 800). A first lead is electrically connected to the first terminal and a second lead is electrically connected to the second terminal (Block 810). A plastic overmold is formed that encapsulates the semiconductor die and at least a portion of the submount (Block 820). Thus, Blocks 800-820 illustrate packaging a semiconductor die in a package that includes a submount, leads and a housing (here the plastic overmold) to provide a preliminary power semiconductor device. A moisture barrier is formed on the preliminary power semiconductor device (Block 830) to provide a power semiconductor device that is configured for mounting on a printed circuit board such as a customer motherboard.

In some cases, moisture barriers are formed on customer motherboards to protect the motherboard from environmental conditions. While this may help protect the components on the motherboard (including any packaged power semiconductor devices mounted thereon) from subsequent moisture ingress, it does not provide any protection from moisture damage that may occur during the solder reflow process used to mount the packaged electronic devices on the motherboard. Additionally, in many cases, it may be desirable to perform a slow baking operation on an electronic device that acts to remove moisture from the device prior to applying any moisture protection. It may not be possible in some cases to perform such a slow baking operation on a printed circuit board, since the printed circuit board may include components that cannot be subjected to such a slow bake process.

While embodiments of the present invention have been discussed above with reference to packaged power semiconductor devices that include a power semiconductor die, it will be appreciated that embodiments of the present invention are not limited thereto. For example, all of the embodiments disclosed herein may include one or more radio frequency (“RF”) semiconductor die in place of the power semiconductor die. For example, the semiconductor die included in the packaged power semiconductor devices may comprise high power, high electron mobility transistor (“HEMT”) amplifiers that are designed to amplify RF signals.

The packaged power semiconductor devices according to embodiments of the present invention may be designed to block voltages of 500 volts or more, and may be rated for currents of at least 25 amps. In some embodiments, the packaged power semiconductor devices may be designed to block voltages of at least 750 volts, 1000 volts, or 1500 volts, and or may be rated for currents of at least 50 amps, at least 75 amps or at least 100 amps. In some embodiments, the packaged power semiconductor devices according to embodiments of the present invention may be designed to block voltages of between 650 and 1700 volts, and may be rated for currents of between 25 and 100 amps.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “attached,” “connected,” or “coupled” to another element, it can be directly attached, directly connected or directly coupled to the other element or intervening elements may be present. In contrast, when an element is referred to as being “directly attached,” “directly connected,” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Herein, the term “plurality” means “two or more.”

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical embodiments of the invention and, although specific terms are employed, they are used in a generic and descriptive sense only and not for purposes of limitation, the scope of the invention being set forth in the following claims.

1. A power semiconductor device, comprising:
a package;
a power semiconductor die within the package; and
a moisture barrier on an upper surface and side surfaces of an exterior of the package.

2. The power semiconductor device of claim 1, wherein the package comprises a plastic overmold.

3. The power semiconductor device of claim 2, wherein the moisture barrier is directly on the plastic overmold.

4. The power semiconductor device of claim 3, wherein the moisture barrier is a conformal moisture barrier that conforms to the plastic overmold.

5. The power semiconductor device of claim 4, wherein the moisture barrier is further on at least part of a bottom of the exterior of the package.

6. The power semiconductor device of claim 2, wherein the semiconductor die has a first terminal and a second terminal, and the package further comprises:
a first lead that is electrically connected to the first terminal, the first lead extending out of the plastic overmold; and
a second lead that is electrically connected to the second terminal, the second lead extending out of the plastic overmold.

7. The power semiconductor device of claim 6, wherein the first lead includes a widened segment that extends through an outer surface of the plastic overmold and a narrowed segment that extends outwardly from the widened segment, and the moisture barrier covers at least a portion of the widened segment.

8-10. (canceled)

11. The power semiconductor device of claim 1, wherein the package includes a submount and a housing, and the moisture barrier completely covers the bottom surface of the submount.

12. The power semiconductor device of claim 2, wherein the moisture barrier comprises at least one of parylene, silicone, polyurethane or an acrylic material.

13. (canceled)

14. The power semiconductor device of claim 2 in combination with a printed circuit board, wherein the power semiconductor device is mounted on the printed circuit board and a portion of the moisture barrier is between the package and the printed circuit board.

15. (canceled)

16. The power semiconductor device of claim 6, wherein the moisture barrier is a first moisture barrier, the power semiconductor device further comprising a second moisture barrier that covers an upper surface and side surfaces of the semiconductor die.

17. The power semiconductor device of claim 16, wherein the second moisture barrier further covers portions of the first and second leads.

18-19. (canceled)

20. The power semiconductor device of claim 6, wherein the moisture barrier covers some but not all of the portions of the first and second leads that are external to the plastic overmold.

21. A power semiconductor device, comprising:
a housing;
a semiconductor die having a first terminal and a second terminal; and
a moisture barrier on an upper surface and side surfaces of the semiconductor die, the moisture barrier positioned between the semiconductor die and the housing.

22. The power semiconductor device of claim 21, wherein the housing comprises a plastic overmold.

23. The power semiconductor device of claim 22, wherein the housing and a submount comprise a package for the power semiconductor device, and the semiconductor die is mounted on an upper surface of the submount.

24. The power semiconductor device of claim 23, wherein the submount comprises a leadframe or a power substrate, and wherein the plastic overmold and the submount together encapsulate the semiconductor die.

25. The power semiconductor device of claim 24, the package further comprising:
a first lead that is electrically connected to the first terminal; and
a second lead that is electrically connected to the second terminal,
wherein the moisture barrier further covers portions of the first and second leads that are within the plastic overmold.

26. The power semiconductor device of claim 22, wherein the moisture barrier directly contacts both the semiconductor die and the plastic overmold.

27-28. (canceled)

29. The power semiconductor device of claim 24, wherein the moisture barrier is a second moisture barrier, the power semiconductor device further comprising a first moisture barrier that is on an exterior of the plastic overmold.

30. The power semiconductor device of claim 29, wherein the plastic overmold is on a top surface and side surfaces of the submount, and wherein at least a portion of a bottom surface of the submount is free of the plastic overmold.

31-33. (canceled)

34. The power semiconductor device of claim 21 in combination with a printed circuit board, wherein the power semiconductor device is mounted on the printed circuit board and a portion of the moisture barrier is between the plastic overmold and the printed circuit board.

35. The power semiconductor device of claim 34, wherein the power semiconductor device is mounted on a printed circuit board and includes a terminal that is mounted on a heat sink, and the moisture barrier electrically insulates the semiconductor die from the heat sink.

36-53. (canceled)
